(19) United States
(12) Patent Application Publication
(10) Pub. No.: US 2016/0226464 A1
(43) Pub. Date: Aug. 4, 2016

(54) ACOUSTIC WAVE ELEMENTS, AND DUPLEXERS AND ELECTRONIC DEVICES USING SAME

(71) Applicant: SKYWORKS PANASONIC FILTER SOLUTIONS JAPAN CO., LTD, Kadoma-Shi (JP)

(72) Inventors: Joji Fujiwara, Osaka-Fu (JP); Yosuke Hamaoka, Osaka Fu (JP); Tetsuya Tsurunari, Osaka-Fu (JP); Hidekazu Nakanishi, Osaka-Fu (JP); Hiroyuki Nakamura, Osaka-Fu (JP); Rei Goto, Osaka-Fu (JP); Hidehito Shimizu, Osaka-Fu (JP)

(21) Appl. No.: 15/093,893

(22) Filed: Apr. 8, 2016

Related U.S. Application Data
(63) Continuation of application No. PCT/JP2014/004929, filed on Sep. 26, 2014.

(30) Foreign Application Priority Data
Oct. 9, 2013 (JP) 2013-211536

(51) Int. Cl. H03H 9/02; H03H 9/64; H03H 9/145

(52) U.S. Cl. CPC H03H 9/02984; H03H 9/14544; H03H 9/02559; H03H 9/64

(57) ABSTRACT

An acoustic wave element that includes a piezoelectric body, an aluminum oxide layer disposed on the piezoelectric body, an electrode disposed on the aluminum oxide layer, and a protection film disposed on the aluminum oxide layer to cover the electrode. The piezoelectric body is formed of a piezoelectric material based on lithium niobate having Euler angles (φ, θ, ψ). The aluminum oxide layer is formed of Al₂O₃. The electrode is configured to excite a main acoustic wave having a wavelength λ. The protection film has a film thickness greater than 0.27λ. The Euler angles satisfy either ψ≦−2φ−3° or −2φ+3°≦ψ and both of −100°≦θ≦−60° and 2φ−2°≦ψ≦2φ+2°.

### CROSS REFERENCE TO RELATED APPLICATIONS

This application is a continuation of International Application Serial No. PCT/JP2014/004929, filed Sep. 26, 2014, which claims priority to Japanese Application No. JP2013-211536, filed Oct. 9, 2013.

### BACKGROUND

FIG. 7 is a cross-sectional schematic view of a conventional acoustic wave element 1. The acoustic wave element 1 includes a piezoelectric body 2, an oxide layer 130 disposed on the piezoelectric body 2, an electrode 3 disposed on the oxide layer 130, and a protection film 4 disposed on the oxide layer 130 to cover the electrode 3.

For example, PCT publication WO2005/034347(A1) discloses a conventional acoustic wave element similar to the acoustic wave element 1.

### SUMMARY OF INVENTION

The present invention relates to an acoustic wave element, a duplexer, and an electronic device using the same.

An acoustic wave element includes a piezoelectric body, an aluminum oxide layer disposed on the piezoelectric body, an electrode disposed on the aluminum oxide layer, and a protection film disposed on the aluminum oxide layer to cover the electrode. The piezoelectric body is formed of a piezoelectric material based on lithium niobate having Euler angles (φ, θ, ψ). The aluminum oxide layer is formed of Al₂O₃. The electrode is configured to excite a main acoustic wave having a wavelength λ, and the protection film has a film thickness greater than 0.27λ. The Euler angles satisfy either ψ≦−2φ−3° or −2φ+3°≦ψ and both of −100°≦θ≦−60° and 2φ−2°≦ψ≦2φ+2°, and the acoustic wave element may suppress an unnecessary spurious signal to be generated.

### BRIEF DESCRIPTION OF THE DRAWINGS

FIG. 1 is a cross-sectional schematic view of an acoustic wave element according to an embodiment.

FIG. 2 is a characteristic diagram of a comparative sample of the acoustic wave element.

FIG. 3 is a characteristic diagram of the acoustic wave element according to the embodiment.

FIG. 4 shows Euler angles of a piezoelectric body of the acoustic wave element according to the embodiment.

FIG. 5 is a block diagram of a duplexer mounted with the acoustic wave element according to the embodiment.

FIG. 6 is a block diagram of an electronic device mounted with the acoustic wave element according to the embodiment.

FIG. 7 is a cross-sectional schematic view of a conventional acoustic wave element.

### DETAILED DESCRIPTION

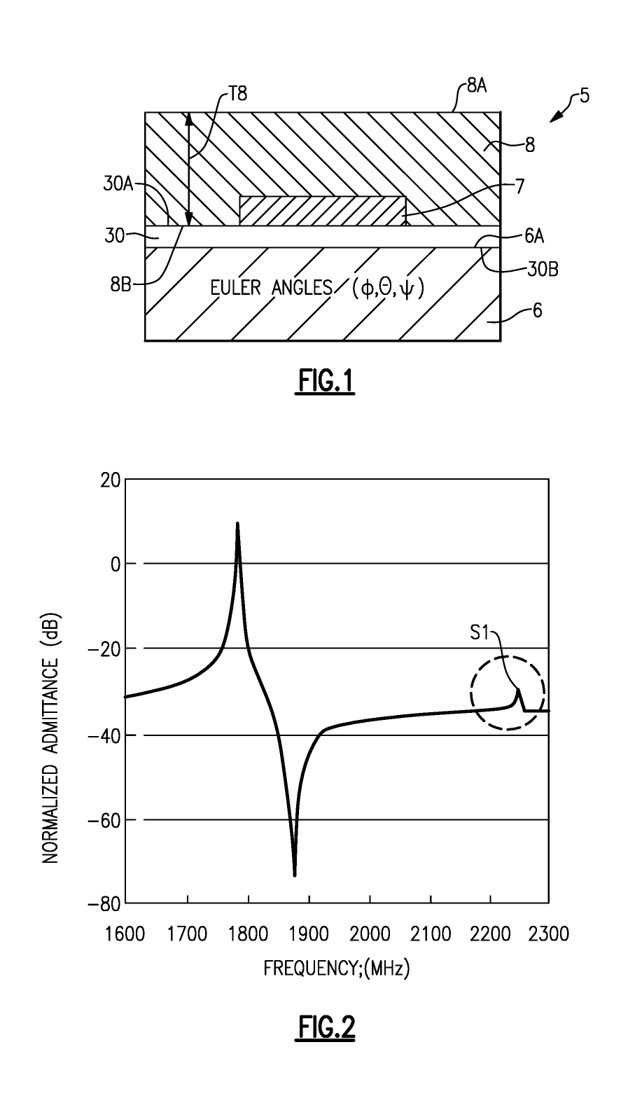

FIG. 1 is a cross-sectional schematic view of an acoustic wave element 5 according to an embodiment. The acoustic wave element 5 includes a piezoelectric body 6, an aluminum oxide layer 30 disposed on a surface 6A of the piezoelectric body 6, an electrode 7 disposed on a surface 30A of the aluminum oxide layer 30, and a protection film 8 disposed on the surface 30A of the aluminum oxide layer 30 to cover the electrode 7. A surface 30B opposite to the surface 30A of the aluminum oxide layer 30 abuts the surface 6A of the piezoelectric body 6. The protection film 8 has a surface 8B abutting the surface 6A of the piezoelectric body 6 and a surface 8A opposite to the surface 8B. The piezoelectric body 6 is a piezoelectric substrate formed of a piezoelectric material based on lithium niobate (LiNbO₃) and the Euler angles (φ, θ, ψ) of the piezoelectric body 6 may satisfy either ψ≦−2φ−3° or −2φ+3 °≦ψ and both of −100°≦θ≦−60° and 2φ−2°≦ψ≦2φ+2°.

The aluminum oxide layer 30 is formed of Al₂O₃, in particular of sapphire. The aluminum oxide layer 30 has the film thickness of 0.001λ or greater and 0.02λ or less.

The electrode 7 includes an elemental metal such as aluminum, copper, silver, gold, titanium, tungsten, molybdenum, platinum or chromium, or an alloy typically containing these elemental metals, or a laminated structure of these elemental metals. The electrode forms an IDT (Inter-Digital Transducer) electrode for exciting a main acoustic wave composed of a SH (Shear Horizontal) wave having a wavelength k, and the electrode is comb-shaped according to the embodiment. The total film thickness of the electrode 7 may generally range from 0.01λ to 0.15λ depending on the density of the electrode.

The protection film 8 is formed, for example, of a silicon oxide (SiO₂) film. In this case, the protection film 8 has a temperature characteristic reverse to that of the piezoelectric body 6 such that increasing the film thickness T8 to be above 0.27λ may improve the frequency temperature characteristic of the acoustic wave element 5. The protection film 8 may be formed of a material other than the silicon oxide film and can preferably protect the electrode 7 from the external environment. The film thickness T8 of the protection film 8 is a film thickness of a portion where the electrode 7 is not formed, and corresponds to a distance from the surface 6A of the piezoelectric body 6 that interfaces the piezoelectric body 6 with the protection film 8 to the surface 8A of the protection film 8. The wavelength λ of the main acoustic wave is twice the average pitch of electrode fingers of the electrode 7 that is comb-shaped.

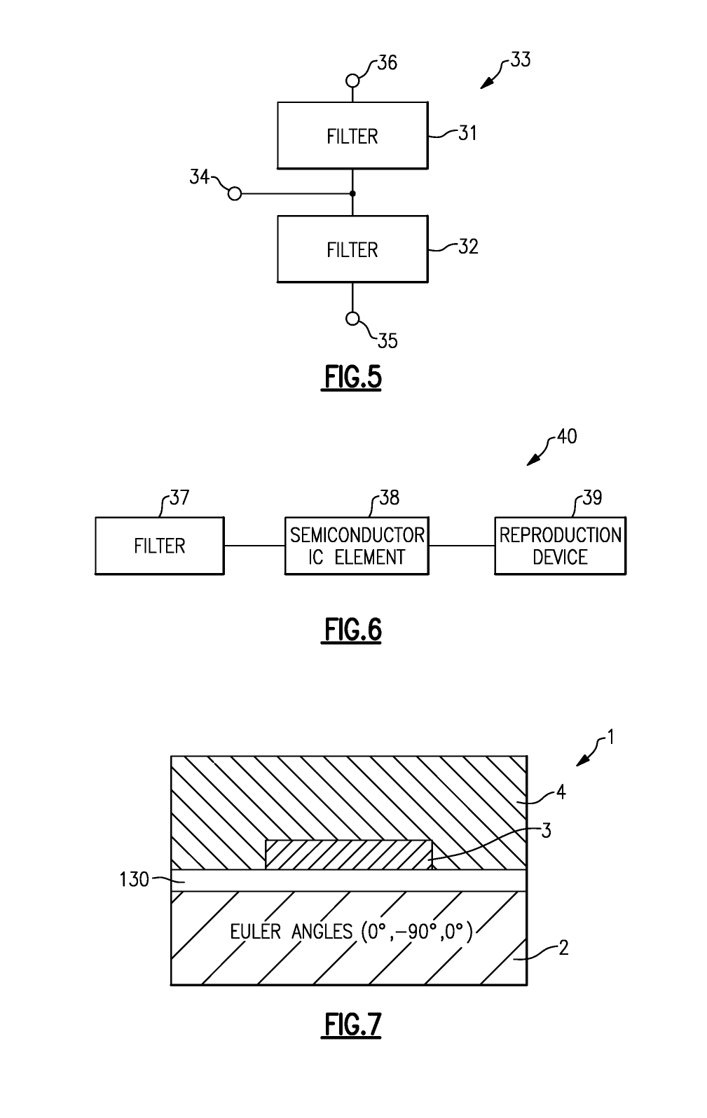

An exemplary sample and a comparative sample were manufactured for the acoustic wave element 5 according to the embodiment. The comparative sample has a structure similar to that of the conventional acoustic wave element 1 shown in FIG. 7. In the comparative sample, the piezoelectric body 2 is formed of a piezoelectric material based on lithium niobate having the Euler angles (0°, −90°, 0°). The oxide layer 130 is formed of Al₂O₃. The electrode 3 is formed of metal such as copper and excites a main acoustic wave having the wavelength λ. The protection film 4 is formed of silicon oxide (SiO₂).

In particular, the oxide layer 130 is formed of a sapphire having the film thickness of 0.006λ. The electrode 3 has the film thickness of 0.062λ. The protection film 4 has the film thickness of 0.35λ.

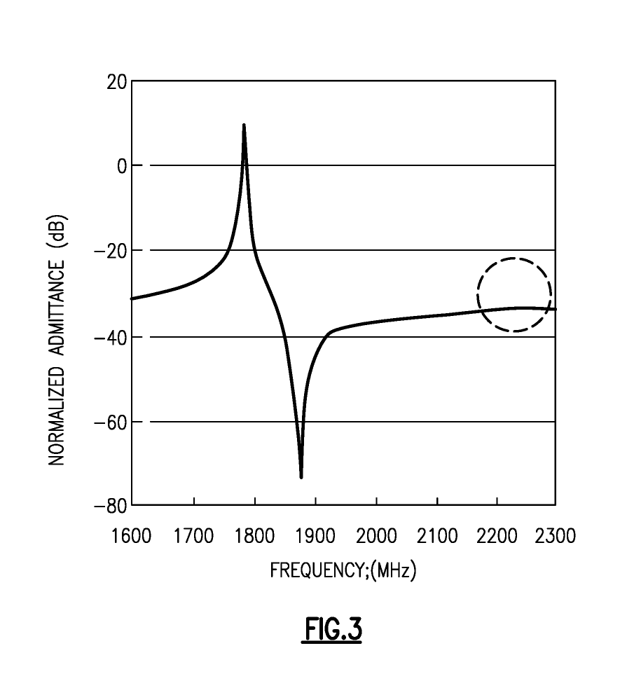

FIG. 2 is a characteristic diagram of the comparative sample of the acoustic wave element. In FIG. 2, the vertical axis represents normalized admittance to the matched value, whereas the horizontal axis represents frequency. In the comparative sample of the acoustic wave element, when the film thickness of the protection film 4 is set, for example, to 0.35λ to improve the temperature characteristic of the acoustic wave element formed of silicon oxide, an unnecessary spurious signal S1 is generated at a frequency approximately 1.3 times the resonant frequency as shown in FIG. 2. Transverse waves having various acoustic velocities are generated in the comparative sample of the acoustic wave element. The unnecessary spurious signal S1 may be attributable to the fastest transverse wave of the transverse waves generated in the acoustic wave element.

The aforementioned fastest transverse wave may degrade the characteristic quality of a filter or a duplexer to which the acoustic wave element of the comparative sample is applied. In order to suppress the unnecessary spurious signal S1, the Euler angles (φ, θ, ψ) of the piezoelectric body 2 are changed via the angles φ and ψ. The unnecessary spurious signal S1 caused by a faster transverse wave can be suppressed no matter whether the angle φ or ψ is changed. This, in turn, would conversely generate another unnecessary spurious signal S1 different from the aforementioned one at a frequency band slightly lower than the resonant frequency. This unnecessary spurious signal S1 may be attributable to a Rayleigh wave.

When the film thickness of the protection film 8 is set thicker than 0.27λ to improve the frequency temperature characteristic of the acoustic wave element 5 according to the embodiment, an unnecessary spurious signal S1 caused by the Rayleigh wave can be suppressed while another unnecessary spurious signal S1 generated around the frequency by the faster transverse wave can be suppressed by setting the angles φ and ψ of the Euler angles (φ, θ, ψ) of the piezoelectric body 6 greater than a predetermined angle and changing the angle φ from 0° to follow ψ=2φ to some extent.

FIG. 3 is a characteristic diagram of the acoustic wave element 5. In FIG. 3, the vertical axis represents normalized admittance (dB), which is a ratio of an admittance value to a value matched during the resonance, whereas the horizontal axis represents frequency (MHz). In the sample of the acoustic wave element 5, the piezoelectric body 6 is formed of a lithium niobate having the Euler angles (−3°, −90°, −3°). The aluminum oxide layer 30 is formed of a sapphire having the film thickness of 0.006λ. The electrode 7 is formed of copper having the film thickness of 0.062λ. The protection film 8 is formed of a silicon oxide (SiO₂) having the film thickness of 0.35λ. As shown in FIG. 3, the acoustic wave element 5 according to the embodiment can suppress an unnecessary spurious signal S1 caused by the Rayleigh wave in the comparative sample as shown in FIG. 2, while suppressing another unnecessary spurious signal S1 generated around a frequency band by the faster transverse wave.

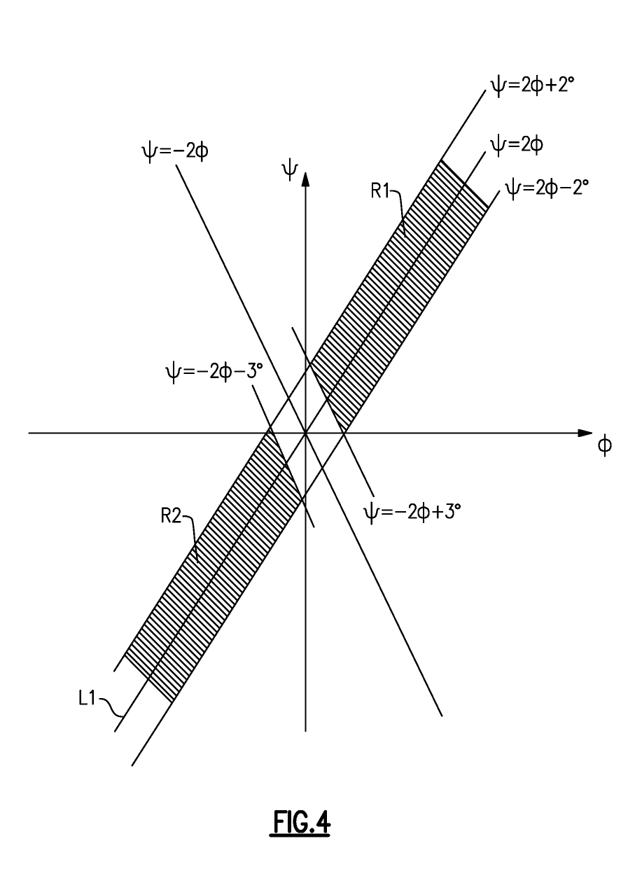

The hatched lines of FIG. 4 show ranges R1 and R2 that the angles y and w of the Euler angles (φ, θ, ψ) can take for the piezoelectric body 6 formed of a piezoelectric material based on lithium niobate. It is to be appreciated that: the angle θ satisfies −100°≦θ≦−60°; the film thickness T8 of the protection film 8 is greater than 0.27λ; and the electrode 7 has a normalized film thickness of 0.062λ and is formed of copper. The line L1 representing the relationship of ψ=2φ shown in FIG. 4 can be construed as representing the relationship between the angles y and ψ especially when the spurious signal S1 (FIG. 2) caused by the Rayleigh wave is suppressed. As shown in FIG. 2, the spurious signal S1 caused by the Rayleigh wave can be suppressed within the range of either ψ≦−2φ−3° or −2φ+3°≦ψ and within the range of the angle ψ of ±2° centered to the line L1, i.e., the range of 2φ−2°≦ψ≦2φ+2°.

FIG. 5 is a block diagram of a duplexer 33 mounted with the acoustic wave element 5 according to the embodiment. The duplexer 33 includes a filter 31, a filter 32 having a passband higher than that of the filter 31, a terminal 36 connected to the filter 31, a terminal 35 connected to the filter 32, and a terminal 34 connected between the filters 31 and 32. The acoustic wave element 5 according to the embodiment is preferably used in the filter 31. There is a possibility that a spurious signal caused by a faster transverse wave in the filter 31 may degrade the characteristic of the filter 32 in a higher passband. Accordingly, configuring the filter 31 by the acoustic wave element 5 according to the embodiment can prevent the characteristic degradation of the filter 32. If the filter 31 is a transmission filter and the filter 32 is a reception filter, the terminal 36 would be an input terminal connected to the transmitter, the terminal 35 would be an output terminal connected to the receiver, and the terminal 34 would be an antenna terminal connected to an antenna.

The acoustic wave element 5 according to the embodiment may be applied to a resonator, and may be applied to a filter such as a ladder-type filter or a DMS filter.

FIG. 6 is a block diagram of an electronic device 40 mounted with the acoustic wave element 5 according to the embodiment. The electronic device 40 includes a filter 37, a semiconductor integrated circuit element 38 connected to the filter 37, and a reproduction device 39 connected to the semiconductor integrated circuit element 38. The filter 37 is configured by the acoustic wave element 5 according to the embodiment. The acoustic wave element 5 may improve the telecommunications quality in the aforementioned resonator, filter, and electronic device 40.

The acoustic wave element of the present invention can suppress the generation of an unnecessary spurious signal and is applicable to an electronic device such as a mobile phone.

What is claimed is:

1. An acoustic wave element comprising:
a piezoelectric body formed from a piezoelectric material based on lithium niobate, the piezoelectric body having Euler angles (φ, θ, ψ) satisfying either ψ≦−2φ−3° or −2φ+3°≦ψ and both of −100°≦θ≦−60° and 2φ−2°≦ψ≦2φ+2°;
an aluminum oxide layer formed from Al₂O₃ disposed on the piezoelectric body;
an electrode disposed on the aluminum oxide layer, the electrode being configured to excite a main acoustic wave having a wavelength λ; and
a protection film disposed on the aluminum oxide layer to cover the electrode, the protection film having a film thickness greater than 0.27λ.

2. The acoustic wave element of claim 1 wherein the protection film is formed from a silicon oxide film.

3. A duplexer comprising:
a first filter including the acoustic wave element of claim 1; and
a second filter having a passband higher than that of the first filter.

4. An electronic device comprising:
the acoustic wave element of claim 1; and
a circuit element connected to the acoustic wave element.

5. The acoustic wave element of claim 2 wherein the protection film has a reverse temperature characteristic to that of the piezoelectric body.

6. The acoustic wave element of claim 1 wherein the aluminum oxide layer is formed from sapphire and has a thickness greater than or equal to 0.001λ and less than or equal to 0.02λ.

7. The acoustic wave element of claim 1 wherein the electrode is formed from elemental metals including aluminum, copper, silver, gold, titanium, tungsten, molybdenum, platinum, and chromium, an alloy including at least two of the elemental metals, or a laminated structure including at least two of the elemental metals.

8. The acoustic wave element of claim 7 wherein the electrode has a thickness greater than or equal to 0.01λ and less than or equal to 0.15λ.

9. The acoustic wave element of claim 8 wherein the electrode is a comb-shaped Inter-Digital Transducer electrode having electrode fingers and the wavelength λ is twice an average pitch of the electrode fingers.

10. The acoustic wave element of claim 1 wherein the piezoelectric body has Euler angles (φ, θ, ψ) of (−3°, −90°, −3°).

11. The acoustic wave element of claim 10 wherein the aluminum oxide layer is formed from sapphire and has a thickness of 0.006λ.

12. The acoustic wave element of claim 11 wherein the electrode is formed from copper and has a thickness of 0.062λ.

13. The acoustic wave element of claim 12 wherein the protection film has a thickness of 0.35λ.

14. The acoustic wave element of claim 1 wherein the acoustic wave element has a resonant frequency and the Euler angles of the piezoelectric body suppress spurious signals at a frequency of approximately 1.3 times the resonant frequency.

15. A method of forming an acoustic wave element comprising:
forming an aluminum oxide layer on a piezoelectric body, the piezoelectric body being formed from a piezoelectric material based on lithium niobate and having has Euler angles (φ, θ, ψ) satisfying either ψ≦−2φ−3° or −2®+3°≦ψ and both of −100°≦θ≦−60° and 2φ−2°≦ψ≦2φ−2°;
forming an Inter-Digital Transducer (IDT) electrode on the aluminum oxide layer, the IDT electrode being configured to excite a main acoustic wave having a wavelength k; and
forming a protection film on the aluminum oxide layer to cover the electrode, the protection film having a film thickness greater than 0.27λ.

16. The method of claim 15 wherein forming the aluminum oxide layer includes forming an aluminum oxide layer having a thickness that is greater than or equal to 0.001λ and less than or equal to 0.02λ.

17. The method of claim 16 wherein forming the IDT electrode on the aluminum oxide layer includes forming an IDT electrode having a thickness greater than or equal to 0.01λ and less than or equal to 0.15λ on the aluminum oxide layer.

18. The method of claim 17 wherein the piezoelectric body has Euler angles (φ, θ, ψ) of (−3°, −90°, −3°).

19. The method of claim 18 wherein forming the IDT electrode on the aluminum oxide layer includes forming a copper IDT electrode on the aluminum oxide layer having a thickness of 0.062λ.

20. The method of claim 16 wherein forming the IDT electrode on the aluminum oxide layer includes forming an IDT electrode having a plurality of electrode fingers on the aluminum oxide layer, the plurality of electrode fingers having an average pitch that is one half λ.
